(19) United States
(12) Patent Application Publication
(10) Pub. No.: US 2023/0170294 A1
(43) Pub. Date: Jun. 1, 2023

(54) SINGLE-DAMASCENE INTERCONNECT HAVING CONTROL OVER CORROSION, DIELECTRIC DAMAGE, CAPACITANCE, AND RESISTANCE

(71) Applicant: International Business Machines Corporation, Armonk, NY (US)

(72) Inventors: Koichi Motoyama, Clifton Park, NY (US); Chanro Park, Clifton Park, NY (US); Hsueh-Chung Chen, Cohoes, NY (US); Raghuveer Reddy Patlolla, Guilderland, NY (US); Cornelius Brown Peethala, Slingerlands, NY (US)

(21) Appl. No.: 17/537,633

(22) Filed: Nov. 30, 2021

(51) Int. Cl. H01L 23/522; H01L 21/768

(52) U.S. Cl. CPC H01L 23/5226; H01L 21/76843; H01L 21/76807; H01L 21/7684; H01L 21/76832

(57) ABSTRACT

Embodiments of the invention include a method of forming an integrated circuit having a single-damascene line-via interconnect. The method includes forming a via trench in a first dielectric layer. A first portion of a barrier layer is formed within the via trench, and a second portion of the barrier layer is formed over the first dielectric layer. A conductive region is formed and includes a conductive via element and a conductive via overburden. The conductive via element is within the via trench; a first portion of the conductive via overburden is over the second portion of the barrier layer; and a second portion of the conductive via overburden is over the conductive via. Planarization is applied to the conductive region and stopped at the second portion of the barrier layer. The conductive via element is coupled at a line-via interface to a conductive line of the single-damascene line-via interconnect.

### BACKGROUND

The present invention generally relates to fabrication methods and resulting structures for multi-layer integrated circuit (IC) wafers. More specifically, the present invention relates to fabrication methods and resulting single-damascene IC interconnect structures having control over metal corrosion, dielectric damage, parasitic capacitance, and vertical-direction resistance.

ICs are fabricated in a series of stages, including a front-end-of-line (FEOL) stage, a middle-of-line (MOL) stage and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts and other structures that communicatively couple to active regions (e.g., gate, source, and drain) of the device element. Layers of interconnection structures are formed above these logical and functional layers during the BEOL stage to complete the IC. Most ICs need more than one layer of wires/lines to form all the necessary connections, and as many as 5-12 layers are added in the BEOL process. The various interconnect structures in the BEOL layers can include the above-described interconnect lines/wires, as well as metal-filled interconnect vias configured to couple one line/wire to another and/or couple one wafer layer to another.

### SUMMARY

Embodiments of the invention are directed to a method of forming a multi-layer integrated circuit (IC) structure. The method includes forming a back-end-of-line (BEOL) region. A single-damascene interconnect is formed in the BEOL region, wherein the single-damascene interconnect includes a conductive via electrically coupled to a conductive line positioned above the conductive via. The conductive via includes a conductive via element and a first portion of a first barrier layer. Forming the single-damascene interconnect includes forming a via trench in a first dielectric layer of the BEOL region. A first barrier layer is formed, wherein a first portion of the first barrier layer is within the via trench, and wherein a second portion of the first barrier layer is over an exposed surface of the first layer of the BEOL region. A conductive region is formed, wherein the conductive region includes the conductive via element and a conductive via overburden. The conductive via element is within the via trench; a first portion of the conductive via overburden is over the second portion of the first barrier layer; and a second portion of the conductive via overburden is over the conductive via element. A planarization operation is applied to the conductive region. The planarization operation is stopped at the second portion of the first barrier layer. The conductive line is electrically coupled to the conductive via at a line-via interface

Embodiments of the invention are directed to a multi-layer IC structure having a single-damascene interconnect in a BEOL region of the multi-layer IC structure. The multi-layer IC structure includes a first dielectric layer of the BEOL region; a second dielectric layer of the BEOL region; a conductive via of the single-damascene interconnect in the first dielectric layer; a conductive line of the single-damascene interconnect in the second dielectric layer; and a dielectric interface between the first dielectric layer and the second dielectric layer. No etch-stop element is present at the dielectric interface.

Embodiments of the invention are directed to a multi-layer IC structure having a single-damascene interconnect in a BEOL region of the multi-layer IC structure. The multi-layer IC structure includes a first dielectric layer of the BEOL region; a second dielectric layer of the BEOL region; a conductive via of the single-damascene interconnect in the first dielectric layer; and a conductive line of the single-damascene interconnect in the second dielectric layer. The conductive via includes a conductive via element and a conductive via barrier layer. The conductive line includes a conductive line element and a conductive line barrier layer. A line-via interface is between the conductive via element and the conductive line element, wherein the conductive line barrier layer is not present at the line-via interface, and wherein the conductive via barrier layer is not present at the line-via interface. A dielectric interface is between the first dielectric layer and the second dielectric layer. A protective cap is on a top surface and sidewalls of the conductive line. An etch-stop layer is over the protective cap and at the dielectric interface.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a three-dimensional view of a portion of an IC wafer that incorporates aspects of the invention;

FIG. 2 depicts a cross-sectional view of a single-damascene interconnect of the IC wafer shown in FIG. 1 in accordance with embodiments of the invention;

FIG. 3 depicts a top-down view of the single-damascene interconnect shown in FIG. 2 taken along line A-A;

FIG. 4 depicts a cross-sectional view of a single-damascene interconnect of the IC wafer shown in FIG. 1 in accordance with embodiments of the invention;

FIGS. 5-17 depict the results of fabrication operations for forming the single-damascene interconnect shown in FIG. 2 and/or the single-damascene interconnect shown in FIG. 4, in which:

FIG. 5 depicts a schematic illustration of a back-end-of-line (BEOL) region of the IC wafer shown in FIG. 1 after fabrication operations according to embodiments of the invention;

FIG. 6 depicts a schematic illustration of a BEOL region of the IC wafer shown in FIG. 1 after fabrication operations according to embodiments of the invention;

FIG. 7 depicts a schematic illustration of a BEOL region of the IC wafer shown in FIG. 1 after fabrication operations according to embodiments of the invention;

FIG. 8 depicts a schematic illustration of a BEOL region of the IC wafer shown in FIG. 1 after fabrication operations according to embodiments of the invention;

FIG. 9 depicts a schematic illustration of a BEOL region of the IC wafer shown in FIG. 1 after fabrication operations according to embodiments of the invention;

FIG. 10 depicts a schematic illustration of a BEOL region of the IC wafer shown in FIG. 1 after fabrication operations according to embodiments of the invention;

FIG. 11 depicts a schematic illustration of a BEOL region of the IC wafer shown in FIG. 1 after fabrication operations according to embodiments of the invention;

FIG. 12 depicts a schematic illustration of a BEOL region of the IC wafer shown in FIG. 1 after fabrication operations according to embodiments of the invention;

FIG. 13 depicts a schematic illustration of a BEOL region of the IC wafer shown in FIG. 1 after fabrication operations according to embodiments of the invention;

FIG. 14 depicts a schematic illustration of a BEOL region of the IC wafer shown in FIG. 1 after fabrication operations according to embodiments of the invention;

FIG. 15 depicts a schematic illustration of a BEOL region of the IC wafer shown in FIG. 1 after fabrication operations according to embodiments of the invention;

FIG. 16 depicts a schematic illustration of a BEOL region of the IC wafer shown in FIG. 1 after fabrication operations according to embodiments of the invention; and

FIG. 17 depicts a schematic illustration of a BEOL region of the IC wafer shown in FIG. 1 after fabrication operations according to embodiments of the invention.

The diagrams depicted herein are illustrative. There can be many variations to the diagram or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two- or three-digit reference numbers. With minor exceptions, the leftmost digit(s) of each reference number correspond to the figure in which its element is first illustrated.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the invention, semiconductor devices are used in a variety of electronic applications. ICs are typically formed from various circuit configurations of semiconductor devices (e.g., transistors, capacitors, resistors, etc.) and conductive interconnect layers (known as metallization layers) formed on semiconductor wafers. Alternatively, semiconductor devices can be formed as monolithic devices, e.g., discrete devices. Semiconductor devices and conductive interconnect layers are formed on semiconductor wafers by depositing many types of thin films of material over the semiconductor wafers, patterning the thin films, doping selective regions of the semiconductor wafers, etc.

In contemporary semiconductor fabrication processes, a large number of semiconductor devices and conductive interconnect layers are fabricated. More specifically, during the first portion of chip-making (i.e., the FEOL stage), the individual components (transistors, capacitors, etc.) are fabricated on the wafer. The MOL stage follows the FEOL stage and typically includes process flows for forming the contacts and other structures that electrically couple to active regions (e.g., gate, source, and drain) of the device element. In the BEOL stage, these device elements are connected to each other through a network of interconnect structures to distribute signals, as well as power and ground. The conductive interconnect layers formed during the BEOL stage serve as a network of pathways that transport signals throughout an IC, thereby connecting circuit components of the IC into a functioning whole and to the outside world. Because there typically isn't enough room on the chip surface to create all of the necessary connections in a single layer, chip manufacturers build vertical levels of interconnects. While simpler ICs can have just a few metallization layers, complex ICs can have ten or more layers of wiring.

BEOL-stage interconnect structures that are physically close to FEOL-stage components (e.g., transistors and the like) need to be small because they attach/join to the components that are themselves very small and often closely packed together. These lower-level lines, which can be referred to as local interconnects, are usually thin and short in length. Global interconnects are higher up in the IC layer structure and travel between different blocks of the circuit. Thus, global interconnects are typically thick, long, and more widely separated local interconnects. Vertical connections between interconnect levels (or layers), called metal-filled vias, allow signals and power to be transmitted from one layer to the next. For example, a through-silicon via (TSV) is a conductive contact that passes completely through a given semiconductor wafer or die. In multi-layer IC configurations, for example, a TSV can be used to form vertical interconnections between a semiconductor device located on one layer/level of the IC and an interconnect layer located on another layer/level of the IC. These vertical interconnect structures include an appropriate metal and provide the electrical connection of the various stacked metallization layers.

Insulating dielectric materials (e.g., an interlayer dielectric (ILD)) are used throughout the layers of an IC to perform a variety of functions including stabilizing the IC structure and providing electrical isolation of the IC elements. Additionally, in order to provide a parasitic resistance and capacitance (RC) level that is sufficiently low to support high signal speed applications, regions of the BEOL dielectric material can be formed from low-k and/or ultra-low-k (ULK) dielectric materials having a dielectric constant of less than silicon dioxide, and the interconnect structures (e.g., wire lines and vias) can be formed from copper-containing material. In general, a low-k dielectric generally has a k value that is less than about 4, and a ULK dielectric generally has a k value that is less than about 2.5.

Interconnect structures are often formed in a stack. For example, in the BEOL layers, a first line (or wire) at one level of the BEOL layers can be electrically coupled to a second line (or wire) at another level of the BEOL layers through a via element. Line-via-line interconnects can be dual-damascene or single-damascene. In a single-damascene line-via-line interconnect, the topmost line, the connecting via, and the bottommost line are separate structures that are coupled together. In a dual damascene interconnect, the topmost line and the connecting via are a unitary (or single) line-via element; the unitary/single line-via element is separate from the bottommost line; and the unitary line-via element and the bottommost line are coupled together. Because the line-via element is a unitary/single structure, dual-damascene interconnects have fewer fabrication steps and less fabrication expense than single-damascene interconnects.

As the critical dimensions of the circuit elements in the device level have been decreased, the dimensions of the various interconnect structures (e.g., metal lines/wires, vias, contact elements, and the like) have also reduced. In some cases, the increased packing density mandates the use of sophisticated metal-containing materials in order to improve reliability and provide a sufficiently high conductivity of the individual metal lines and vias. For example, to achieve a desired level of reliability in complex metallization systems, interconnect structures can be formed from copper in combination with a liner/barrier layer(s) in order to achieve the required electrical performance and to minimize electro-migration and/or surface migration failure mechanisms. Copper is a highly conductive material so forming lines and/or vias from high conductivity copper improves overall IC performance. In addition, copper can be fabricated into smaller structures than other conductive materials such as aluminum, which allows interconnect structures to keep pace with transistor size scaling. Copper is also more durable and reliable. The liner/barrier layers surround the particular interconnect structure (e.g., line, contact, and/or via) and serves multiple functions. For example, the liner/barrier can function as a barrier to prevent metals in the interconnect structure from migrating into the surrounding ILD in which the interconnect structures are formed. Additionally, the liner/barrier can provide adhesion between the metal interconnect structure and the surrounding ILD.

With continued reductions in device dimensions, a limiting factor for the operating speed of the final IC product is no longer the individual transistor element but the electrical performance of the complex interconnect/wiring system that is formed above the device level of the IC. More specifically, as IC feature sizes continue to decrease, the aspect ratio, (i.e., the ratio of height/depth to width) of features such as interconnect structures generally increases. High aspect ratio single-damascene interconnect structures can be easier to fabricate and provide better performance than high aspect ratio dual damascene interconnects, which can offset the fabrication savings of dual damascene interconnects.

There are, however, challenges to overcome with single-damascene interconnects. For example, so-called vertical-direction resistivity can be a problem in single-damascene interconnects, particularly where the single-damascene interconnect includes small dimensions and high aspect ratio line and via structures. In general, interconnect structures provide current paths that move horizontally in all directions along a major surface of a given level of the IC, as well as current paths that move current in a vertical direction from one level of the IC to another. Although the resistivity of interconnect structures in the horizontal and vertical directions must be kept sufficiently low, with narrower, taller (i.e., higher-aspect-ratio) interconnect structures, managing vertical-direction resistivity (or vertical-direction resistance) is a challenge. For example, the liner/barrier and cap materials that are most effective in providing barrier, adhesion, and reliability functions are also relatively high resistivity materials that slow down current flow through the single-damascene interconnect stack in the vertical direction. As the aspect ratio of single-damascene interconnect structure stacks continues to increase, the negative impact of the high resistivity liner/barrier and cap layers of each single-damascene interconnect element (e.g., a first line, a via, and a second line) in the stack on current flowing through the single-damascene interconnect stack in the vertical direction also increases.

Another challenge with single-damascene interconnects is that known single-damascene fabrication processes can result in corrosion at the interface between the topmost single-damascene line and the single-damascene via. In general, corrosion can be defined as the deterioration of a material (usually a metal) because of a reaction with the environment. Most metals are found in nature as ores. The manufacturing process of converting these ores into metals involves the input of energy (e.g., added electrons). During a corrosion reaction the energy added in manufacturing is released (e.g., striped electronics), and the metal is returned to its oxide state.

Another challenge with single-damascene interconnects is that known single-damascene fabrication operations can damage the BEOL dielectric in which the single-damascene interconnect is formed. Still another challenge with single-damascene interconnects is that known single-damascene fabrication operations can result in increased parasitic capacitance. The increased parasitic capacitance can result from the previously-described damaged BEOL dielectric, as well as the presence of etch-stop layers between the BEOL dielectric layers.

Turning now to an overview of the aspects of the invention, embodiments of the invention provide fabrication methods and resulting single-damascene IC interconnect structures having improved control over metal corrosion, dielectric damage, parasitic capacitance, and vertical-direction resistance. Embodiments of the invention provide improved control over vertical-direction resistivity (or vertical-direction resistance) by providing a single-damascene interconnect structures in which the high resistivity liners/barriers (e.g., Co/TaN) are selectively placed at the interfaces between metal interconnect elements and the surrounding dielectric trench, and selectively omitted at the interfaces between one interconnect element (e.g., a line) and another interconnect element (e.g., a via). By removing the high resistivity liner/barrier elements from the interfaces between single-damascene interconnect elements, the vertical-direction resistivity (or vertical-direction resistance) of current moving vertically through the single-damascene interconnect is significantly reduced or eliminated.

Embodiments of the invention provide improved control over corrosion by providing a single-damascene interconnect structure in which energy is prevented from being released (e.g., through stripped electrons) from the single-damascene metal interconnect elements during fabrication, thereby preventing the single-damascene metal interconnect from corroding. In general metal corrosion requires an anode (e.g., the via element where electrons will be lost and corrosion will occur); a cathode (e.g., the barrier layer metal where electrons will be gained); an electrolyte environment (e.g., the CMP slurry); electrical connection between the anode and the cathode; and a potential difference between the anode and the cathode. Where the anode is a Cu via element, and where the cathode is a Ta or TaN barrier layer metal, the Cu anode is less noble than the TaN (or Ta) cathode, which means that the Cu anode has the potential to be have a negative electric potential with respect to the TaN (or Ta). If all of the conditions for corrosion are present, the less noble metal will corrode by losing electrons to the more noble metal.

In known single-damascene interconnect architectures, the via is formed in a so-called “via” dielectric layer; the line below the via is formed in a first so-called “line” dielectric layer; and the line above the via is formed in a second so-called “line” dielectric layer. Because the via density (e.g., greater than zero and less than about 5%) in the via dielectric layer is much less than the line density (e.g., about 80% or more) in each of the line dielectric layers, and because the line in the first line dielectric layer is electronically isolated, the ions (or free electrons) in the CMP slurry used to form and planarize the via can concentrate at the via top locally, which causes the planarized via (higher electric potential) to lose electrons to the via's barrier layer metal (lower electric potential). In the process of giving up electrons, the molecules of planarized via metal actually migrate to the barrier layer metal, which results in cavities in the post-CMP via metal.

In some embodiments of the invention, electron-loss and resulting metal corrosion are prevented by forming a via trench in a dielectric layer of a BEOL region; depositing a barrier layer over the dielectric layer and within the via trench; forming a conductive metal (e.g., copper) over the dielectric layer and via trench; planarizing the conductive metal; and stopping the planarization process at the barrier layer that is over the dielectric layer such that the planarized conductive metal and the portion of the barrier layer that is over the dielectric layer are at substantially the same electric potential. By maintaining the conductive metal and the portion of the barrier layer that is over the dielectric at the same electric potential, one of the elements that is necessary for metal corrosion to occur is eliminated. As previously noted, metal corrosion requires an anode (e.g., the via element where electrons will be lost and corrosion will occur); a cathode (e.g., the barrier layer where electrons will be gained); an electrolyte environment (e.g., the CMP slurry); electrical connection between the anode and the cathode; and a potential difference between the anode and the cathode. Where the anode is a Cu via element, and where the cathode is a Ta or TaN barrier layer, the Cu anode is less noble than the TaN (or Ta) cathode, which means that the Cu anode has the potential to be have a negative electric potential with respect to the TaN (or Ta). However, because the CMP process applied to the conductive metal overburden, in accordance with aspects of the invention, is stopped on the barrier layer that is across substantially the entire dielectric layer, corrosion of the planarized via metal does not occur.

Embodiments of the invention provide improved control over dielectric damage and parasitic capacitance. As previously noted, known single-damascene fabrication operations can damage the BEOL dielectric in which the single-damascene interconnect is formed. Additionally, with decreased interconnect dimensions in the BEOL region, the potential for single-damascene interconnects and related structures to create unwanted metal-dielectric-metal regions is increased. The increased parasitic capacitance can result from the previously-described damaged BEOL dielectric, as well as the presence of etch-stop layers (e.g., SiCN) between the BEOL dielectric layers. Accordingly, embodiments of the invention provide improved control over dielectric damage and parasitic capacitance by utilizing a sacrificial dielectric layer during fabrication of the line portion of the single-damascene interconnect. Accordingly, any damage that results from line-trench and line fabrication operations is done to the sacrificial dielectric layer. After the line-trench and line fabrication operations are completed, the damaged sacrificial dielectric layer is replaced with a non-damaged non-sacrificial dielectric layer. In some embodiments of the invention, damage to the sacrificial dielectric layer can be minimized by forming the sacrificial dielectric layer from a dielectric material (e.g., an oxide) that is stronger and easier to pattern, etch, and planarize than low-k or ULK dielectric materials. Embodiments of the invention further provide improved control over parasitic capacitance by providing a single-damascene interconnect structure in which selected portions of an etch-stop layer are removed, which eliminates the possibility that the removed portions of the selected etch-top layer will form metal-dielectric-metal capacitance structures with dielectric layers and other etch-stop layers in the BEOL region of the single-damascene interconnect.

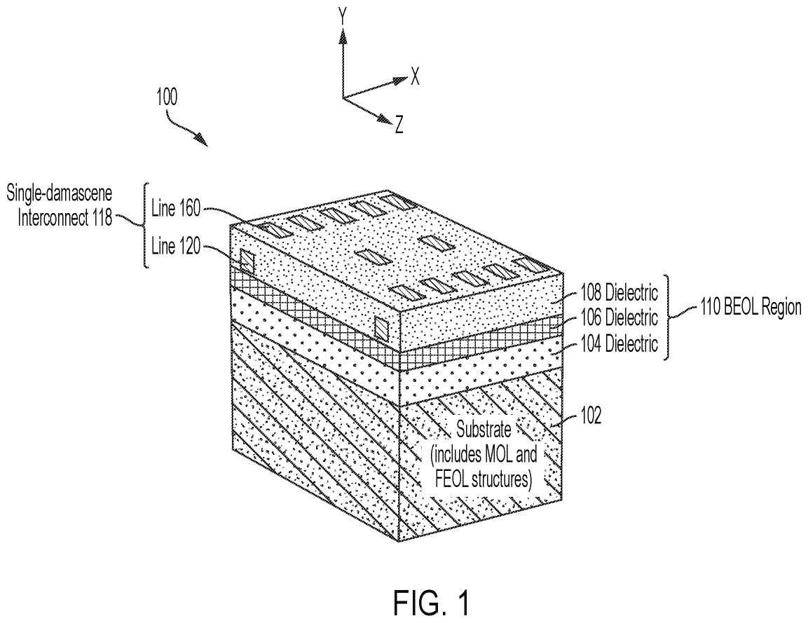

Turning now to a more detailed description of aspects of the present invention, FIG. 1 depicts a portion of an IC wafer 100 having a single-damascene interconnect 118. In accordance with aspects of the invention, the single-damascene interconnect 118 is configured and arranged to provide improved control over metal corrosion, dielectric damage, parasitic capacitance, and vertical-direction resistance. The IC wafer 100 includes a substrate 102 having middle-of-line (MOL) and front-end-of-line (FEOL) structures (not shown separately) formed in MOL and FEOL regions (not shown separately) of the substrate 102. A multi-layered BEOL region 110 is formed over the substrate 102. The BEOL region 110 includes a BEOL dielectric 104, a BEOL dielectric 106, and a BEOL dielectric 108, configured and arranged as shown. Although three BEOL dielectrics 104, 106, 108 are shown in FIG. 1, the multi-layered BEOL region 110 can be provided with any number of dielectric layers.

Insulating dielectric materials are used throughout the layers of the IC wafer 100 to perform a variety of functions including stabilizing the IC wafer 100 and providing electrical isolation of the current-carrying IC elements (active devices, contacts, lines, vias, and the like). Additionally, in order to provide a parasitic resistance and capacitance (RC) level that is sufficiently low to support high signal speed applications, the BEOL region 110 can include low-k and/or ultra-low-k (ULK) dielectric materials having a dielectric constant less than silicon dioxide, and the interconnect structures (e.g., the single-damascene interconnects 118) can be formed from copper-containing material. In general, a low-k dielectric has a k value that is less than about 4, and a ULK dielectric has a k value that is less than about 2.5.

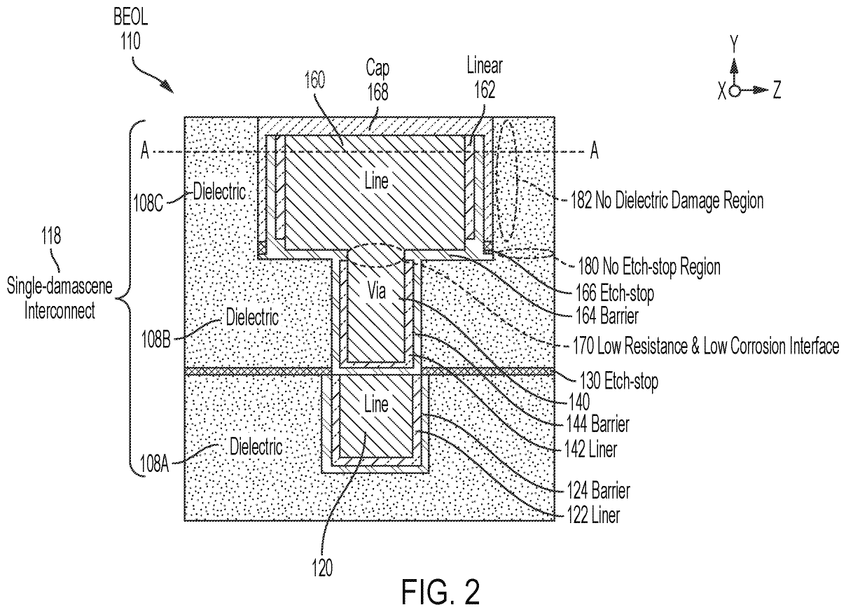

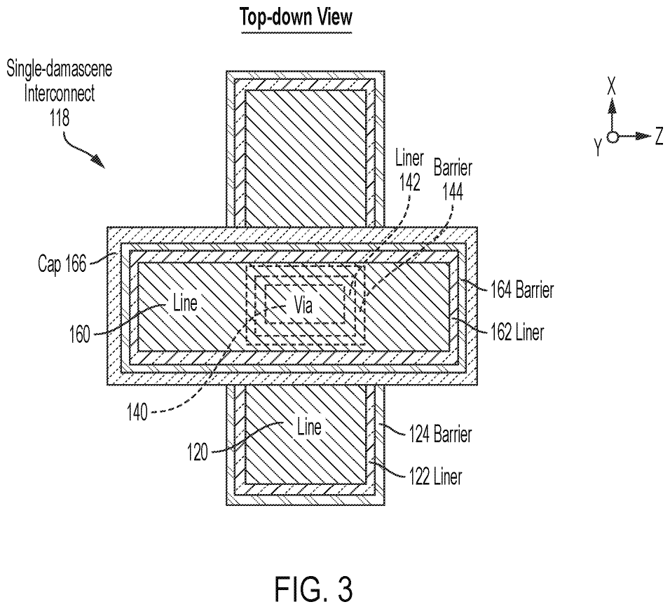

The BEOL dielectric 108 includes a network of the novel single-damascene interconnects 118 formed therein. In accordance with aspects of the invention, some or all of the BEOL dielectrics 104, 106, 108 in the BEOL region 110 can be provided with the novel single-damascene interconnects 118. The network of novel single-damascene interconnects 118 can be implemented as a network of lines (or wires) 120 (e.g., Cu), metal-filled vias 140 (e.g., Cu) (shown in FIGS. 2 and 3), and lines (or wires) 160 (e.g., Cu), configured to transmit electrical signals throughout the IC wafer 100. In general, the lines 120, 160 conduct current horizontally in a predetermine pattern extending along the Z-axis and/or the X-axis, and the metal-filled vias 140 conduct current vertically (or in a vertical direction) along the Y-axis.

In accordance with aspects of the invention, the single-damascene interconnects 118 are formed in a “single-damascene” configuration, wherein the line 120, the metal-filled via 140, and the line 160 are each separate structures that are coupled together. By contrast, in a dual damascene interconnect, the topmost line and the connecting via are a unitary (or single) line-via element; the unitary/single line-via element is separate from the bottommost line 120; and the unitary line-via element and the bottommost line 120 are coupled together. Each of the line 120, the via 140 (shown in FIG. 2), and the line 160 is fabricated using single-damascene fabrication operations, which include, generally, depositing a blanket dielectric film (e.g., the BEOL dielectric 108) as a layer of the BEOL region 110; lithographically patterning the blanket dielectric file; and applying a reactive ion etch (RIE) to the blanket dielectric film to create a trench that follows the pattern of the line 120, the via 140, or the line 160. The trench is coated by a refractory metal liner/barrier (e.g., Co/TaN) (not shown in FIG. 1) followed by a thin sputtered metal (e.g., Cu) seed layer (not shown separately). The seed layer enables the electrochemical deposition (ECD) of a thick metal layer that fills up the trench. Excessive metal is removed and the top surface of the blanket dielectric film is planarized by a planarization process such as CMP, thereby forming the line 120, the via 140, or the line 160.

As described in greater detail subsequently herein, in accordance with aspects of the invention, conventional single-damascene structures and fabrication processes are modified to form the single-damascene interconnects 118 such that they provide improved control over metal corrosion, dielectric damage, parasitic capacitance, and vertical-direction resistance. Embodiments of the invention apply to a network of single-damascene interconnects 118 where the via density (e.g., greater than zero and less than about 5%) in the BEOL dielectric 108 is much less than the line density (e.g., about 80% or more) in the BEOL dielectric 108. The density of an interconnect in a dielectric layer can be measured as the interconnect pattern density (IPD). In general, IPD is the fractional area of a layer's surface that is occupied by the metal interconnects within a given window size. The quality of CMP processes is driven by a variety of factors including the IPD of the BEOL layer being planarized.

FIG. 2 depict a cross-sectional view of the single-damascene interconnect 118 (shown in FIG. 1), and FIG. 3 depicts a top-down view (taken along line A-A of FIG. 2) of the single-damascene interconnect 118. FIG. 3 primarily illustrates the top-down profile of the line 120, the via 140, and the line 160. As shown in FIGS. 2 and 3, and as best shown in the cross-sectional view of FIG. 2, the single-damascene interconnect 118 is formed in dielectric regions 108A, 108B, 108C of the BEOL dielectric 108 (shown in FIG. 1). The single-damascene interconnect 118 includes the line 120 electrically coupled through the via 140 to the line 160. In accordance with aspects of the invention, a liner layer 122 (e.g., Co) and a barrier layer 124 (e.g., TaN or Ta) are one sidewalls and a bottom surface of the line 120; and a liner layer 142 (e.g., Co) and a barrier layer 144 are formed on sidewalls and a bottom surface of the via 140. Additionally, in accordance with aspects of the invention, a liner layer 162 and a barrier layer 164 are formed on selective portions of the sidewalls and selective portions of a bottom surface of the line 160. The liner/barrier layers 122, 124, 142, 144, 162, 164 serves multiple functions. For example, the barrier layers 124, 144, 164 can function as a barrier to prevent metals in the liners/lines 122/120, 162/160 and the liner/via 142/140 from migrating into the surrounding dielectric regions 108A, 108B, 108C. Additionally, the liner/barrier layers 122/124, 142/144, 162/164 can provide adhesion between the line/via/line 120/140/160 and the surrounding dielectric regions 108A, 108B, 108C. A protective cap 168 is over and around a top surface and sidewalls of the line/liner/barrier 160/162/164.

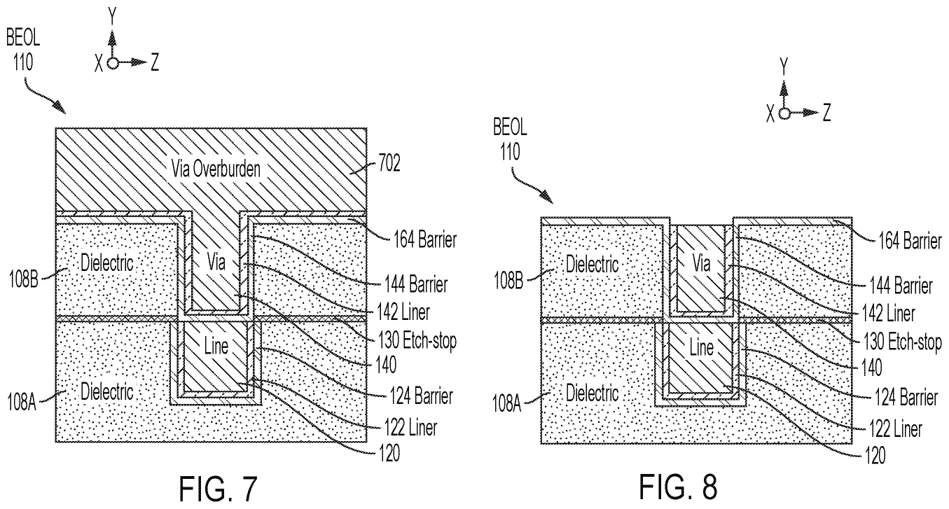

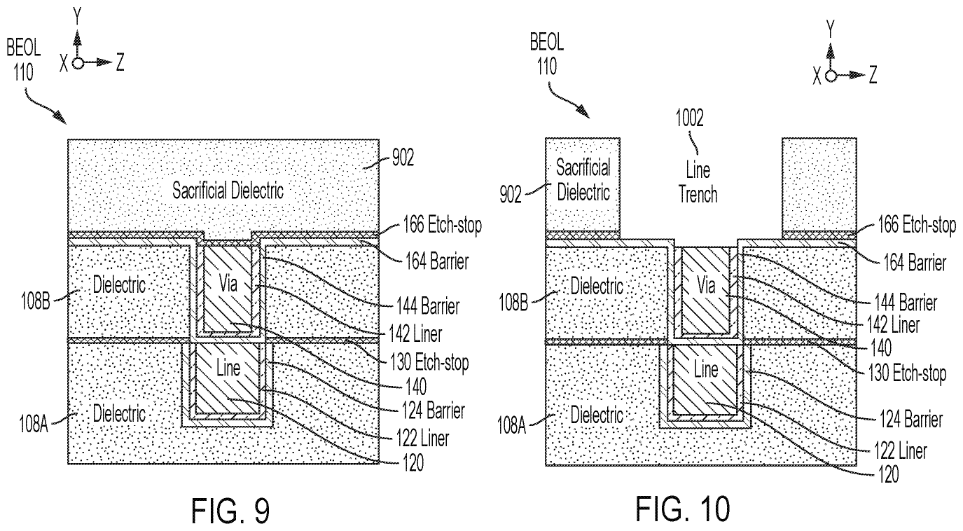

In accordance with aspects of the invention, the single-damascene interconnect 118 provides improved control over metal corrosion, dielectric damage, parasitic capacitance, and vertical-direction resistance. Embodiments of the invention provide improved control over vertical-direction resistivity (or vertical-direction resistance) by selectively providing the barrier layer 164 at interfaces between the line 160 and the dielectric regions 108B, 108C, and by selectively not providing the barrier layer 164 at a low-resistance & low corrosion (LRLC) interface 170 between the line 160 and the via 140. Embodiments of the invention provide improved control over metal corrosion by fabricating the single-damascene interconnect 118 in a manner (e.g., as shown in FIGS. 7-17) that eliminates at least one of the prerequisites for metal corrosion to occur. Embodiments of the invention provide improved control over dielectric damage and parasitic capacitance by providing the dielectric region 108C with no line-fabrication-related damage in general, and specifically by providing the dielectric region 108C with no line-fabrication-related damage in a no-damage region 182 that extends around sidewalls of the line 160. In addition to the performance benefits that result from improved integrity of the dielectric region 108C, parasitic capacitance is reduced by the no-damage region 182. Embodiments of the invention achieve the no damage region 182 by utilizing a sacrificial dielectric region 902 (shown in FIG. 9) during fabrication of the line 160. Accordingly, any damage that results from line-trench and line fabrication operations (e.g., as shown in FIGS. 9-14) is applied to the sacrificial dielectric region 902. After the line-trench and line fabrication operations are completed, the sacrificial dielectric region 902 is replaced with the dielectric region 108C. Embodiments of the invention further provide improved control over parasitic capacitance by selectively locating the etch-stop 166 (e.g., SiCN) such that an interface between the dielectric region 108B and the dielectric region 108C does not include the etch-stop layer 166, thereby forming a no etch-stop region 180 that extends around sidewalls at lower regions of the line 160.

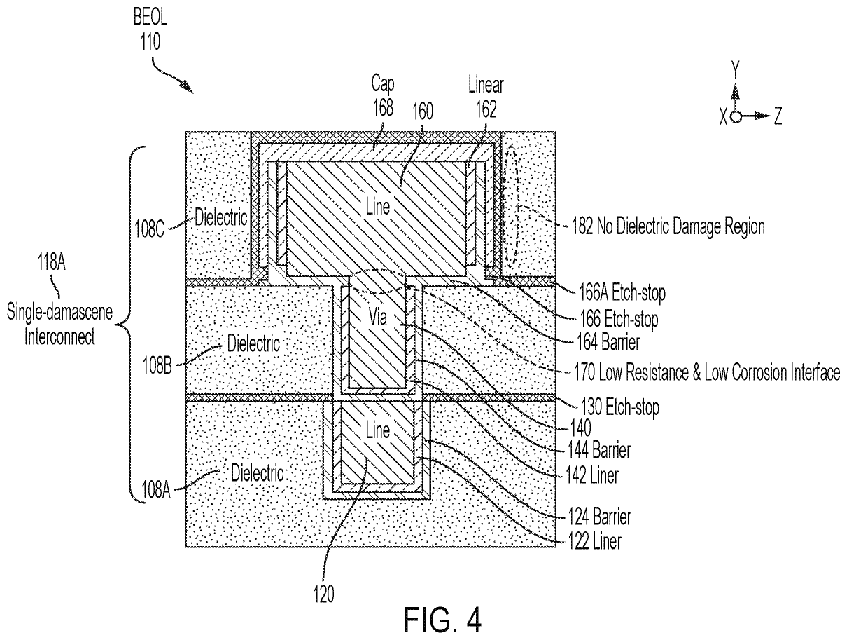

FIG. 4 depicts a cross-sectional view of a single-damascene interconnect 118A in accordance with aspects of the invention. The single-damascene interconnect 118A is substantially the same as the single-damascene interconnect 118 shown in FIGS. 2 and 3 except that in the single-damascene interconnect 118A an etch-stop 166A (e.g., SiCN) is provided over the protective cap 168 and at the interface between the dielectric region 108B and the dielectric region 108C. The etch-stop 166A improves adhesion integrity between the dielectric region 108B and the dielectric region 108C at the expense of not achieving the previously-described reduction in parasitic capacitance that results from the no etch-stop region 180. Based on the specific design requirements of the IC wafer 100, the tradeoff that results from providing the etch-stop 166A can be warranted.

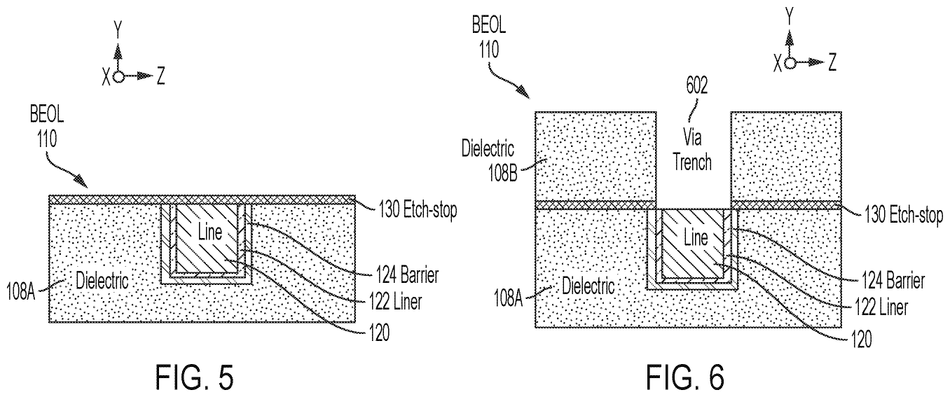

FIGS. 5-17 depict the results of fabrication operations for forming the single-damascene interconnects 118, 118A shown in FIGS. 2-4 in the BEOL region 110 of the IC wafer 100. A variety of well-known single-damascene IC fabrication operations are suitable for forming the various stages of the BEOL region 110 shown in FIGS. 5-17. Accordingly, in the interest of brevity, such well-known fabrication operations are either omitted or described and illustrated at a high level.

FIG. 5 depicts a schematic illustration of the BEOL region 110 after fabrication operations according to embodiments of the invention, wherein known IC fabrication techniques have been used to form the dielectric region 108A, the line 120, the liner layer 122, the barrier layer 124, and an etch stop 130, configured and arrange as shown. Known layer deposition techniques (e.g., ALD) can be used to deposit the dielectric region 108A. A line-trench is formed in the dielectric region 108A in accordance with an interconnect layout pattern of the IC wafer 100. In aspects of the invention, the line-trench can be formed by lithographically patterning the dielectric region 108A and applying a reactive ion etch (RIE) to create the line-trench. The line-trench is coated with the barrier layer 124 (e.g., a refractory meal such as Ta or TaN) and the liner layer 122 (e.g., Co) followed by a thin sputtered metal seed layer (e.g., Cu) (not shown separately). The metal seed layer allows for the ECD of a thick metal conductor layer (not shown) that fills up the line-trench and covers the dielectric region 108A. A planarization technique (e.g., CMP) is used to remove excessive metal in the conductor layer and planarize the conductor layer and the dielectric region 108A. An etch-stop 130 (e.g., SiCN) is conformally deposited.

In FIG. 6, known IC fabrication techniques (e.g., ALD) have been used to form the dielectric region 108B over the etch-stop 130. A via-trench 602 is formed in the dielectric region 108B and the exposed portion of etch-stop 130 is removed in accordance with the interconnect layout pattern of the IC wafer 100. In aspects of the invention, the via-trench 602 can be formed by lithographically patterning the dielectric region 108B and applying a reactive ion etch (RIE) to create the via-trench 602 and expose surfaces of the liner layer 122 and a top surface of the line 120.

In FIG. 7, the via-trench 602 (shown in FIG. 6) and the dielectric region 108B are coated with the barrier layer 144 (e.g., a refractory meal such as Ta or TaN), the barrier layer 164, and the liner layer 142 (e.g., Co) followed by a thin sputtered metal seed layer (e.g., Cu) (not shown separately). The barrier layer 144 is within the via-trench 602, and the barrier layer 164 is on a top surface of the dielectric region 108B. The metal seed layer enables the ECD of a thick metal via overburden 702 that fills up the via-trench 602 and covers the dielectric region 108B, the barrier layer 164.

In FIG. 8, a planarization technique (e.g., CMP) has been used to remove the via overburden 702 and a portion of the liner layer 142. The planarization technique is configured to stop on the barrier layer 164, thereby exposing the barrier layer 164, portions of the liner layer 142, and a top surface of the via 140. In some embodiments of the invention where the overburden 702 is Cu, an endpoint system can be used for the Cu CMP in order to detect (through an endpoint signal) that a surface of the barrier layer 164 is exposed during Cu CMP. In some embodiments of the invention, Cu over-polishing can be used to ensure that no Cu residue remains on the exposed surface of the barrier layer 164. Because Cu CMP has high polishing rate on the Cu overburden and the Co liner layer 142, and has a very low polishing rate on the TaN barrier layer 164, there is some Cu via 140 and Co liner layer 142. In some embodiments of the invention, the over-polishing process with highly selective Cu slurry or a wet etching process can be applied to recess the liner layer 142 and the via 140. The via 140 is a conductive via element. The via 140 combined with the liner 142 and/or the barrier 144 are a conductive via.

Referring still to FIG. 8, in accordance with aspects of the invention, improved control over vertical-direction resistivity (or vertical-direction resistance) of the single-damascene interconnect 118 is achieved by selectively providing the high resistivity barrier layer 164 such that it is not on the top surface of the via 140, wherein the top surface of the via 140 will form part of the LRLC interface 170 (shown in FIGS. 2 and 4). In accordance with aspects of the invention, improved control over corrosion is achieved by preventing energy from being released (e.g., through stripped electrons) from top surface of the via 140, thereby preventing the top surface of the via 140 from corroding. In general metal corrosion requires an anode (e.g., the via 140 where electrons will be lost and corrosion will occur); a cathode (e.g., the barrier layer 164 where electrons will be gained); an electrolyte environment (e.g., the CMP slurry used during the planarization operation); electrical connection between the anode and the cathode; and a potential difference between the anode and the cathode. Where the via 140 (i.e., the anode) is a Cu, and where the barrier layer 164 (i.e., the cathode) is a Ta or TaN, the Cu is less noble than the TaN (or Ta), which means that the Cu (i.e., the anode) has the potential to be have a negative electric potential with respect to the TaN (or Ta) (i.e., the cathode). If all of the conditions for corrosion are present, the less noble Cu metal will corrode by losing electrons to the more noble Ta or TaN metal.

Because the via density (e.g., greater than zero and less than about 5%) in the dielectric region 108B is much less than the line density (e.g., about 80% or more) in the dielectric region 108A, and because the line 120 in the dielectric layer region 108A is electronically isolated, the ions (or free electrons) in the CMP slurry used to planarize the via overburden 702 (shown in FIG. 7) are available to, potentially, concentrate at the top surface of the via 140. The ions can, if all of the conditions for corrosion to occur are present, causes the planarized via 140 (higher electric potential) to lose electrons. However, embodiments of the invention prevent this electron-loss and resulting metal corrosion from occurring by stopping the planarization of the via overburden 702 at the barrier layer 164 such that the via 140 and the barrier layer 164 that is over the dielectric region 108B are at substantially the same electric potential. By maintaining the via 140 and the barrier layer 164 that is over the dielectric region 108B at substantially the same electric potential, one of the elements that is necessary for metal corrosion to occur is eliminated. Accordingly, the top surface of the via 140 will form part of the LRLC interface 170 (shown in FIGS. 2 and 4).

In FIG. 9, known IC fabrication operations (e.g., ALD) have been used to deposit an additional layer of etch-stop material (e.g., SiCN) (not shown separately), which, when combined with the etch-stop 130 (shown in FIG. 8), form an etch-stop 166 over the barrier layer 164, a portion of the liner layer 142, and the via 140. Additionally, known IC fabrication operations (e.g., ALD) have been used to deposit a sacrificial dielectric region 902 over the etch-stop 166. In accordance with aspects of the invention, the sacrificial dielectric region 902 can be formed from a dielectric material (e.g., an oxide) that is stronger and easier to pattern, etch, and planarize than low-k or ULK dielectric materials.

In FIG. 10, a line-trench 1002 is formed in the sacrificial dielectric region 902 and through a portion of the etch-stop 166 in accordance with the interconnect layout pattern of the IC wafer 100. In aspects of the invention, the line-trench 1002 can be formed by lithographically patterning the sacrificial dielectric region 902 and applying directional RIEs to directionally etch through the sacrificial dielectric region 902 and exposed portions of the etch-stop 166 to create the line-trench 1002 and expose surfaces of a portion of the barrier layer 164, portions of the liner layer 142, and a top surface of the via 140.

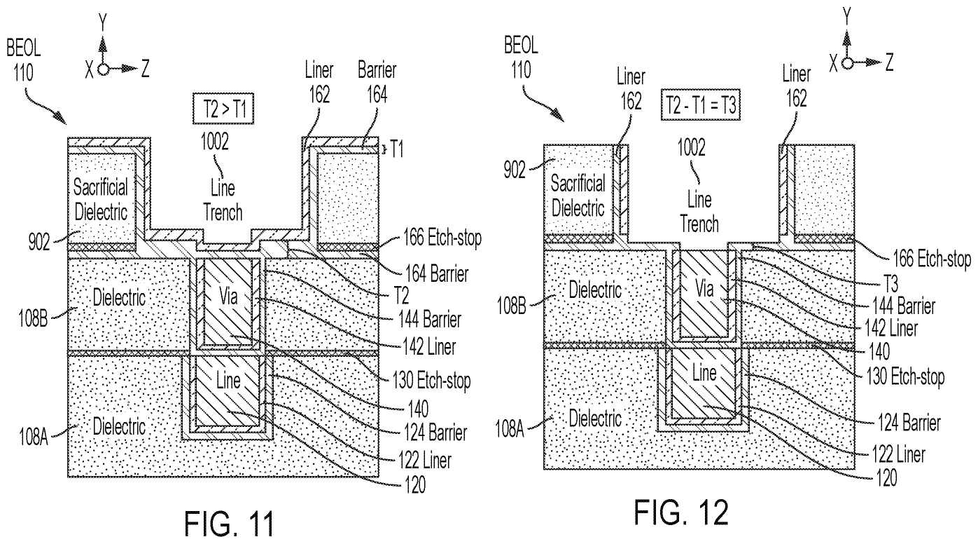

In FIG. 11, known IC fabrication operations (e.g., ALD) have been used to conformally deposit additional barrier layer material over the BEOL region 110 such that the barrier layer 164 is on a top surface of the sacrificial dielectric region 902, on sidewalls of the line-trench 1002, and on a bottom surface of the line-trench 1002. Because of the exposed portions of the barrier layer 164 formed in FIG. 10, after deposition of the additional barrier layer material, the portion of the barrier layer 164 that is within the line-trench 1002 and over the dielectric region 108B has a second thickness T2, which is greater than a first thickness T1 of the portions of the barrier layer 164 that are over the top surface of the sacrificial dielectric region 902, on sidewalls of the line-trench 1002, and over the top surface of the via 140. Additionally, known IC fabrication operations (e.g., ALD) have been used to conformally deposit the liner layer 162 over the exposed surfaces of the barrier layer 164.

In FIG. 12, known IC fabrication operations (e.g., directional RIEs) have been used to remove the liner layer 162 from the horizontal surfaces and leave the liner layer 162 on sidewalls of the line-trench 1002. Directional etching (e.g., directional RIEs) has been used to remove the first thickness T1 of the barrier layer 164 from the horizontal surfaces, thereby removing the barrier layer 164 from the top surface of the sacrificial dielectric region 902, and removing the barrier layer 164 from the top surface of the via 140. For the portion of the barrier layer 164 that has the second thickness T2, the directional RIE reduces the second thickness T2 by the first thickness T1, thereby forming a portion of the bottom surface of the line-trench 1002 as the barrier layer 164 having a third thickness T3. The second thickness T2 minus the first thickness T1 equals the third thickness T3.

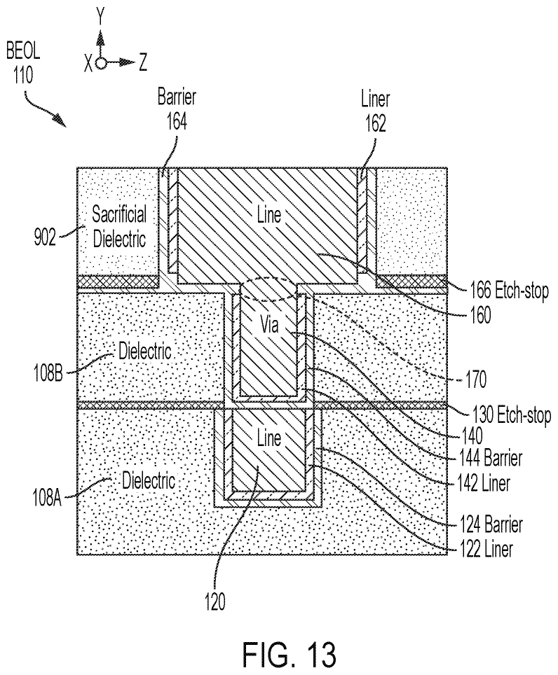

In FIG. 13, known IC fabrication operations have been used to form the line 160 in the line-trench 1002 (shown in FIG. 11). The line 160 can be formed by coating the line-trench 1002 with a thin sputtered metal seed layer (e.g., Cu) (not shown separately). The metal seed layer enables the ECD of a thick metal overburden (not shown) that fills up the line-trench 1002 and covers portions of the sacrificial dielectric region 902. A planarization technique (e.g., CMP) has been used to remove the overburden 702 and planarize the BEOL region 110. After the fabrication operations depicted in FIG. 13, the LRLC interface 170 is formed between the line 160 and the via 140 without a barrier layer in accordance with aspects of the invention, thereby providing improved control over vertical-direction resistivity (or vertical-direction resistance) and metal corrosion (using the fabrication operations depicted at FIGS. 7 and 8).

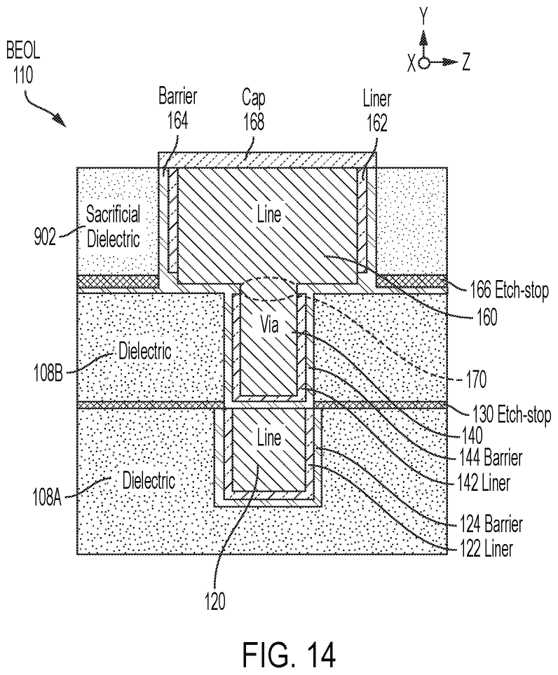

In FIG. 14, known IC fabrication operations (e.g., selective deposition) have been used to selectively deposit the protective cap 168 (e.g., Ru or Co) on end portions of the barrier layer 164, end portions of the liner layer 162, and a top surface of the line 160.

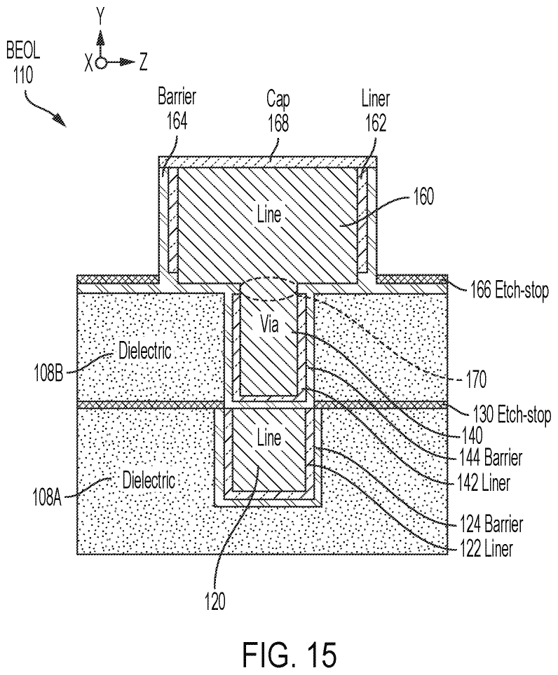

In FIG. 15, known fabrication techniques have been used to selectively remove the sacrificial dielectric region 902 (shown in FIG. 14) from the BEOL region 110.

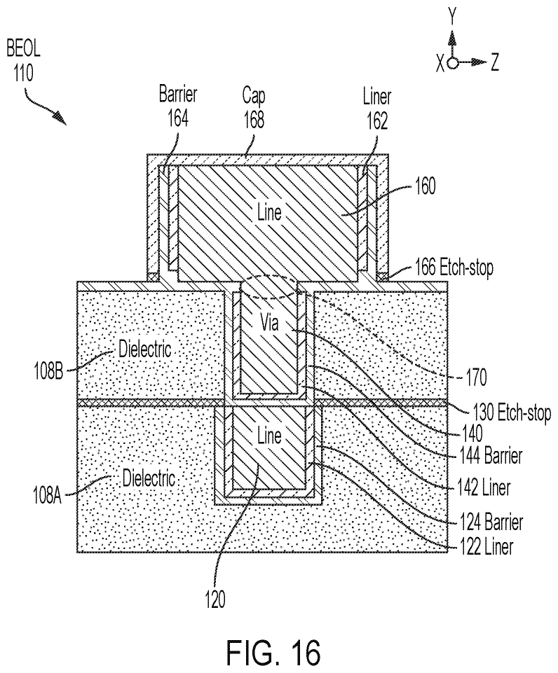

In FIG. 16, known IC fabrication operations (e.g., selective deposition) have been used to selectively deposit additional regions of the protective cap 168 (e.g., Ru or Co) on exposed surfaces of the barrier layer 164. Known IC fabrication operations (e.g., directional RIE) have been used to remove exposed portions of the etch-stop 166, leaving a small region of the etch-stop 166 beneath the protective cap 168.

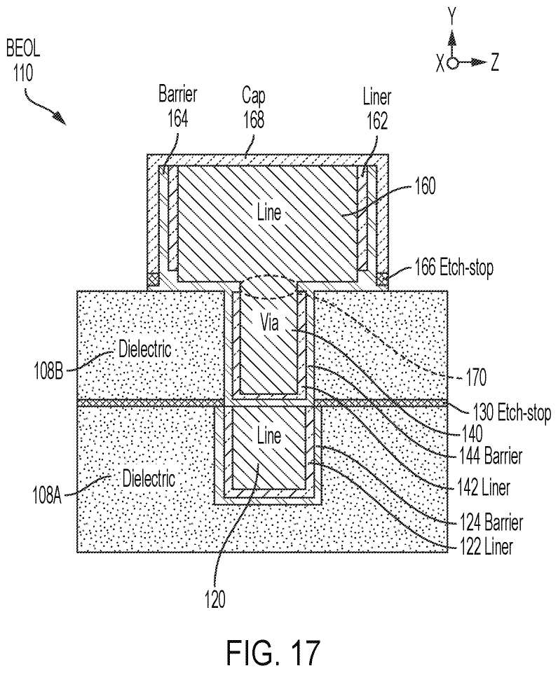

In FIG. 17, known IC fabrication techniques (e.g., directional RIE) have bene used remove exposed portions of the barrier layer 164.

After the fabrication operations depicted in FIG. 17, additional fabrication operations can be used to form the single-damascene interconnect 118 shown in FIG. 2. More specifically, after the fabrication operations depicted in FIG. 17, known IC fabrication techniques (e.g., ALD) can be used to deposit dielectric material (not shown) over the BEOL region 110. The dielectric material is planarized to form the dielectric region 108C. In accordance with aspects of the invention, the dielectric region 108C can be formed from a low-k and/or ULK dielectric material, which provide a parasitic resistance and capacitance (RC) level that is sufficiently low to support high signal speed applications. In embodiments of the invention, suitable materials for the low-k/ULK materials of the dielectric region 108C can include, for example, fluorine-doped silicon dioxide, porous organosilicate glass material (e.g., SiCOH), porous silicon dioxide, and organic polymeric materials such as polyimide, polynorbornenes, benzocyclobutene, and hydrogen sisesquioxane, and the like.

After the fabrication operations depicted in FIG. 17, additional fabrication operations can be used to form the single-damascene interconnect 118A shown in FIG. 4. The single-damascene interconnect 118A is substantially the same as the single-damascene interconnect 118 shown in FIGS. 2 and 3 except that in the single-damascene interconnect 118A an etch-stop 166A (e.g., SiCN) is provided over the protective cap 168 and the dielectric region 108B before the dielectric region 108C is formed. The etch-stop 166A improves adhesion integrity between the dielectric region 108B and the dielectric region 108C at the expense of not achieving the previously-described reduction in parasitic capacitance that results from the no etch-stop region 180. Based on the specific design requirements of the IC wafer 100, the tradeoff that results from providing the etch-stop 166A can be warranted.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

“Planarization” and “planarize” as used herein refer to a material removal process that employs at least mechanical forces, such as frictional media, to produce a substantially two-dimensional surface. A planarization process may include chemical mechanical polishing (CMP) or grinding. CMP is a material removal process that uses both chemical reactions and mechanical forces to remove material and planarize a surface.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the invention, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical mechanical polishing (CMP), and the like. Reactive ion etch (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method of forming a multi-layer integrated circuit (IC) structure, the method comprising:
forming a back-end-of-line (BEOL) region; and
forming a single-damascene interconnect in the BEOL region;
wherein the single-damascene interconnect comprises a conductive via electrically coupled to a line above the conductive via;
wherein the conductive via comprises a conductive via element and a first portion of a first barrier layer;
wherein forming the single-damascene interconnect in the BEOL region comprises:
forming a via trench in a first dielectric layer of the BEOL region;
forming the first barrier layer, wherein the first portion of the first barrier layer is within the via trench, and wherein a second portion of the first barrier layer is over an exposed surface of the first dielectric layer of the BEOL region;
forming a conductive region comprising the conductive via element and a conductive via overburden, wherein the conductive via element is within the via trench, wherein a first portion of the conductive via overburden is over the second portion of the first barrier layer, and wherein a second portion of the conductive via overburden is over the conductive via element;
applying a planarization operation to the conductive region;
stopping the planarization operation at the second portion of the first barrier layer; and
coupling the conductive line to the conductive via at a line-via interface.

2. The method of claim 1, wherein forming the single-damascene interconnect in the BEOL region comprises providing the first dielectric layer of the BEOL region with an interconnect pattern density that is greater than zero and less than or equal to about 5%.

3. The method of claim 1, wherein:
stopping the planarization operation at the second portion of the first barrier layer substantially prevents the second portion of the first barrier layer and the conductive region from being planarized at the same time; and
substantially preventing the second portion of the first barrier layer and the conductive region from being planarized at the same time substantially prevents corrosion at a planarized surface of the conductive region.

4. The method of claim 1, wherein forming the single-damascene interconnect in the BEOL region further comprises forming the conductive line within a sacrificial second dielectric layer of the BEOL region.

5. The method of claim 4, wherein forming the conductive line comprises forming a conductive line-trench in the sacrificial second dielectric layer.

6. The method of claim 5, wherein forming the conductive line-trench damages portions of the sacrificial second dielectric layer, thereby converting the sacrificial second dielectric layer to a damaged sacrificial second dielectric layer.

7. The method of claim 6, wherein forming the single-damascene interconnect in the BEOL region further comprises replacing the damaged sacrificial second dielectric layer of the BEOL region with a non-sacrificial non-damaged third dielectric layer of the BEOL region.

8. The method of claim 1, wherein forming the single-damascene interconnect in the BEOL region further comprises:
forming an etch-stop layer over selected regions of the second portion of the first barrier layer:
forming a sacrificial second dielectric layer of the BEOL region over the etch-stop layer;
forming the conductive line within the sacrificial second dielectric layer;
wherein forming the conductive line comprises forming a conductive line-trench in the sacrificial second dielectric layer;
subsequent to forming the conductive line-trench, removing the sacrificial second dielectric layer, a portion of the etch-stop layer that is underneath the sacrificial second dielectric layer, and a portion of the second portion of the first barrier layer that is underneath the sacrificial second dielectric layer; and
forming a non-sacrificial third dielectric layer of the BEOL region in a space that was occupied by the sacrificial second dielectric layer of the BEOL region.

9. The method of claim 8, wherein the non-sacrificial third dielectric layer of the BEOL region interfaces directly with the first dielectric layer of the BEOL region.

10. The method of claim 1, wherein forming the single-damascene interconnect in the BEOL region further comprises:
forming a second dielectric layer of the BEOL region; and
forming the conductive line within a conductive line-trench of the second dielectric layer;
wherein the conductive line comprises a conductive line element and a second barrier layer;
wherein forming the conductive line comprises forming the line-via interface as a direct coupling of the conductive line element to the conductive via element; and
wherein the first barrier layer and the second barrier layer are not present at the line-via interface between the conductive line element and the conductive via element.

11. The method of claim 1, wherein forming the single-damascene interconnect further comprises:
forming a second dielectric layer of the BEOL region;
forming a conductive line-trench in the second dielectric layer;
wherein a bottom surface of the conductive line-trench comprises the second portion of the first barrier layer having a first thickness; and
forming a second barrier layer on a top surface of the second dielectric layer, sidewalls of the conductive line-trench, and the bottom surface of the conductive line-trench;
wherein the bottom surface of the conductive trench comprises a third barrier layer that comprises the second barrier layer and the second portion of the first barrier layer, the third barrier layer having a second thickness; and
wherein the second thickness is greater than the first thickness.

12. The method of claim 11, wherein forming the single-damascene interconnect in the BEOL region further comprises applying a directional etch to:
the second barrier layer on the top surface of the second dielectric layer;
the second barrier layer on the sidewalls of the conductive line-trench; and
the third barrier layer on the bottom surface of the conductive line-trench.

13. The method of claim 12, wherein applying the directional etch:
removes the second barrier layer from the top surface of the second dielectric layer; and
leaves a portion of the third barrier layer on the bottom surface of the conductive line-trench.

14. The method of claim 13, wherein:
the portion of the third barrier layer on the bottom surface of the conductive line-trench comprises a third thickness; and
the second thickness minus the first thickness equals the third thickness.

15. A multi-layer integrated circuit (IC) structure having a single-damascene interconnect in a back-end-of-line (BEOL) region of the multi-layer IC structure, the multi-layer IC structure comprising:
a first dielectric layer of the BEOL region;
a second dielectric layer of the BEOL region;
a conductive via of the single-damascene interconnect in the first dielectric layer;
a conductive line of the single-damascene interconnect in the second dielectric layer; and
a dielectric interface between the first dielectric layer and the second dielectric layer;
wherein no etch-stop element is present at the dielectric interface.

16. The multi-layer IC structure of claim 15, wherein:
the conductive via comprises a conductive via element and a conductive via barrier layer; and
the conductive line comprises a conductive line element and a conductive line barrier layer.

17. The multi-layer IC structure of claim 16 further comprising a line-via interface between the conductive via element and the conductive line element, wherein the conductive line barrier layer is not present at the line-via interface.

18. The multi-layer IC structure of claim 17, wherein the conductive via barrier layer is not present at the line-via interface.

19. The multi-layer IC structure of claim 18 further comprising a protective cap on a top surface and sidewalls of the conductive line.

20. A multi-layer integrated circuit (IC) structure having a single-damascene interconnect in a back-end-of-line (BEOL) region of the multi-layer IC structure, the multi-layer IC structure comprising:
a first dielectric layer of the BEOL region;
a second dielectric layer of the BEOL region;
a conductive via of the single-damascene interconnect in the first dielectric layer;
a conductive line of the single-damascene interconnect in the second dielectric layer;
wherein the conductive via comprises a conductive via element and a conductive via barrier layer;
wherein the conductive line comprises a conductive line element and a conductive line barrier layer;
a line-via interface between the conductive via element and the conductive line element;
wherein the conductive line barrier layer is not present at the line-via interface;
wherein the conductive via barrier layer is not present at the line-via interface;
a dielectric interface between the first dielectric layer and the second dielectric layer;
a protective cap on a top surface and sidewalls of the conductive line; and
an etch-stop layer over the protective cap and at the dielectric interface.
